(19) United States
(12) Patent Application Publication
(10) Pub. No.: US 2009/0068344 A1
(43) Pub. Date: Mar. 12, 2009

(54) System and method for manufacturing thin film electrical devices

(76) Inventors: Vincent Cannella, Beverly Hills, MI (US); George Uzoni, West Bloomfield, MI (US); Buddie Dotter, Shelby Township, MI (US)

Correspondence Address: ENERGY CONVERSION DEVICES, INC., 2956 WATERVIEW DRIVE, ROCHESTER HILLS, MI, 48309, US

(21) Appl. No.: 12/220,934

(22) Filed: Jul. 30, 2008

Related U.S. Application Data
(60) Provisional application No. 60/962,713, filed on Jul. 31, 2007.

(51) Int. Cl. C23C 16/54; B05D 5/12

(52) U.S. Cl. 427/58; 118/719

(57) ABSTRACT

A system for manufacturing a thin film electrical device is provided in accordance with an exemplary embodiment. The system includes a chamber and a gas gate. The chamber includes accumulating apparatus therein configured for gathering a portion of the substrate within the chamber. The gas gate provides fluid communication between a pressure region of the chamber and a second pressure region.

### GOVERNMENT INTEREST

This invention was made, at least in part, under U.S. Government, National Institute of Standards and Technology (NIST), Award No. 70NANB3H3030. The Government may have rights in this invention.

### FIELD OF THE INVENTION

This invention relates generally to a system for manufacturing quantities of thin film electrical devices and in particular to a fabrication system having one or more deposition processes.

### BACKGROUND OF THE INVENTION

It is intended that this disclosure apply to thin film electrical devices such as inorganic and organic semiconductor devices and circuitry, organic photovoltaic devices, inorganic films, inorganic inks, and the like. It is further contemplated that this disclosure applies to a thin film electrical device (TFED) having a multilayered intermediate structure over which an electrical device portion is disposed, wherein the intermediate structure is configured to minimize or prevent water vapor and oxygen from diffusing through a substrate of the TFED and degrading the electrical portion. The TFEDs may be used to perform electrical functions such as, but not limited to, conducting electricity, processing information, generating electrical current, generating light, displaying information, etc.

Generally, the fabrication of a thin film electrical device employs many manufacturing processes. Manufacturing a thin film electrical device often involves utilization of different deposition processes for forming various layers of the TFED. For example, in one embodiment of a TFED one layer is formed by screen printing or a slot die process at atmospheric pressure while another layer is formed by a vacuum evaporation deposition or a physical vapor deposition process. Moreover, it is desirable to utilize a roll-to-roll fabrication process with a continuous substrate to manufacture large volumes of TFEDs economically. Manufacturing TFEDs in a large scale, roll-to-roll process involving deposition of various materials over a continuous substrate poses special challenges compared to batch manufacturing TFEDs.

Transitioning portions of the TFED between regions of vastly different pressures for processing often requires careful selection of sealing and pumping provisions to maintain one or more of the regions at a desirable pressure. Further, it may also be desirable to maintain the environment integrity of one or more of the regions, for example to maintain a region at a unique gaseous environment and/or minimize contaminates in the region. In one application such as transitioning from atmospheric pressure to a vacuum deposition chamber, multiple sealing devices can be utilized with large capacity pumping apparatus to maintain the vacuum pressure region, a complicated and costly arrangement.

Additionally, in an effort to maintain operational integrity of the TFED it is often not desirable to contact a previously deposited layer during a transition from one manufacturing process to another manufacturing process. For some embodiments of TFEDs, at one stage of the manufacturing process it may be desirable to process a stationary portion of the continuous substrate while other portions of the continuous substrate are moving.

Accordingly, the inventors herein have recognized a need for a fabrication system configured to produce quantities of TFEDs, wherein the fabrication system utilizes one or more deposition processes for precisely depositing layers of materials over a continuous substrate.

### SUMMARY OF THE INVENTION

A system for manufacturing a thin film electrical device on a substrate is provided in accordance with an exemplary embodiment. The system includes a chamber and a gas gate. The chamber includes accumulating apparatus therein configured for gathering a portion of the substrate within the chamber. The gas gate provides fluid communication between a pressure region of the chamber and a second pressure region.

A system for manufacturing a thin film electrical device on a substrate is provided in accordance with another exemplary embodiment. The system includes a deposition apparatus, a first gas evacuation apparatus, a first chamber, second gas evacuation apparatus, and a gas gate. The deposition apparatus is configured for depositing material over a portion of the substrate within a chamber of the deposition apparatus. The first gas evacuation apparatus is in fluid communication with the chamber of the deposition apparatus. The first chamber includes accumulating apparatus therein configured for gathering a portion of the substrate within the first chamber. The second gas evacuation apparatus is in fluid communication with the first chamber.

The gas gate provides fluid communication between the first chamber and the chamber of the deposition apparatus, wherein the substrate with an accumulated portion of substrate in the first chamber extends through the first chamber and into the chamber of the deposition apparatus and through the gas gate; and the gas gate, the gas evacuation apparatus of the chamber of the deposition apparatus and the gas evacuation apparatus of the first chamber are configured so an operational pressure in the chamber of the deposition apparatus is lower than an operational pressure in the first chamber.

A system for manufacturing a thin film electrical device on a substrate is provided in accordance with another exemplary embodiment. The system includes a deposition apparatus, first gas evacuation apparatus, a first chamber, a second chamber, second gas evacuation apparatus, third gas evacuation apparatus, a first gas gate, and a second gas gate. The deposition apparatus is configured for depositing material over a portion of the substrate within a chamber of the deposition apparatus. The first gas evacuation apparatus is in fluid communication with the chamber of the deposition apparatus. The deposition apparatus is positioned between the first chamber and the second chamber. Each of the first and second chambers includes accumulating apparatus therein configured for gathering a portion of the substrate within the corresponding first and second chamber. The second gas evacuation apparatus is in fluid communication with the first chamber. The third gas evacuation apparatus is in fluid communication with the second chamber.

The first gas gate provides fluid communication between the first chamber and the deposition apparatus. The second gas gate provides fluid communication between the chamber of the deposition apparatus and the second chamber, and wherein the substrate with an accumulated portion of substrate in the first chamber and an accumulated portion of substrate in the second chamber extends through the first chamber, through the chamber of the deposition apparatus and through the second chamber and through the first and second gas gates; and the first and second gas gates, the first, second and third gas evacuation apparatus are configured so an operational pressure in the chamber of the deposition apparatus is lower than an operational pressure in each of the first and second chambers.

A method of utilizing a system for manufacturing a thin film electrical device on a substrate is provided in accordance with an exemplary embodiment. The system includes deposition apparatus, a first chamber and a second chamber, a first gas gate and a second gas gate. The deposition apparatus is positioned between the first chamber and the second chamber. The first gas gate provides fluid communication between the first chamber and the chamber of the deposition apparatus. The second gas gate provides fluid communication between the chamber of the deposition apparatus and the second chamber. Each of the first chamber, the second chamber and the chamber of the deposition apparatus include gas evacuation apparatus connected thereto in fluid communication with the corresponding chamber.

The method includes extending the substrate through the first chamber, the chamber of the deposition apparatus and the second chamber and through the first and second gas gates, wherein each of the first and second chambers includes therein an accumulated portion of the substrate. The method further includes operating the deposition apparatus to deposit material over a portion of the substrate, wherein an operational pressure within the chamber of the deposition apparatus is lower than an operational pressure in each of the first and second chambers.

### BRIEF DESCRIPTION OF THE DRAWINGS

FIG. 1 is cross sectional view of an example of a thin film electrical device contemplated of being manufactured by an embodiment of a fabrication system disclosed herein;

FIG. 2 is cross sectional view of an air-to-vacuum system in accordance with an exemplary embodiment of the fabrication system; and

FIG. 3 is a cross sectional view of a gas gate utilized in the air-to-vacuum system of FIG. 2.

### DETAILED DESCRIPTION OF THE INVENTION

Disclosed herein are apparatus utilized in embodiments of a fabrication system for manufacturing thin film electrical devices having electrically functional material disposed over a substrate or web of material. Thin film electrical devices contemplated of being manufactured by embodiments of the fabrication system include inorganic and organic semiconductor devices and circuitry, organic photovoltaic devices, inorganic films, inorganic inks, and the like.

It is further contemplated that an embodiment of the fabrication system is configured to manufacture thin film electrical devices having a multilayered intermediate structure over which an electrical device portion is disposed, wherein the intermediate structure is configured to minimize or prevent water vapor and oxygen from diffusing through a substrate of the TFED and degrading the electrical portion. In addition to forming the intermediate structure, the fabrication system can also be configured to form at least a part of the electrical device portion disposed over the intermediate structure.

Embodiments of the fabrication system are configured to manufacture a thin film organic electrical device (TFOED) for use in radio frequency transmitters and receivers, energy generating devices, integrated circuits, and organic light emitting devices.

Exemplary embodiments of the fabrication system disclosed hereinbelow are configured to include one or more deposition processes for precisely depositing material layers, such as in a patterned configuration, over a continuous substrate. The fabrication system is configured to transition the continuous substrate through multiple pressure regions and gaseous environments. The fabrication system is further configured to transition the continuous substrate through various stages of the system where components of the system are configured to not contact a previously deposited material layer on the continuous substrate. The fabrication system is further configured so a portion of the continuous substrate is stationary during a deposition process while another portion of the continuous substrate is moving.

In exemplary embodiments of the fabrication system, certain components of the system are configured to precisely control various properties of electrically functional materials such as chemical composition, microstructure, deposition area, and deposition thickness. For example, the system includes components configured to maintain the substrate in a desirable orientation through one or more manufacturing processes to form the TFED. The system can be further configured for depositing an electrically functional material, an active material, with a specific microstructure on a specifically defined area of the substrate to specific thicknesses. The specifically defined area may for example include a precise coating pattern.

As used herein, “electrically functional organic material” refers to material that includes carbon containing compounds configured to perform exemplary functions such as but not limited to receiving, processing and storing data, converting energy, and releasing data or light (for example, displaying information). As used herein, “thin-film” refers to layers that have a thickness of less than 10 microns and more specifically less than 1 micron. When used to describe layers deposited over a substrate, “thin-film layer” may be used to describe a single layer of material or multiple layers of material.

Embodiments of the fabrication system may include apparatus or systems such as a payoff system, substrate conditioning system, deposition system, curing system, substrate alignment system, substrate-movement and position control system, laminator, gas evacuation apparatus such as vacuum pump, accumulator, gas gate, and a drive system. In one exemplary embodiment, the continuous substrate moves through an accumulator, one or more gas gates, and a vacuum region, and/or an air-to-vacuum (ATV) system. The ATV system is configured for transitioning from an atmospheric pressure region to a region having a vacuum therein, wherein a deposition process may be performed over the substrate. In another exemplary embodiment, the fabrication system is arranged as a roll-to-roll fabrication system, wherein a supply, a roll, of a continuous substrate is directed through a plurality of process apparatus of the system and then collected, as a roll, as a semi-finished or finished product. Depending on a particular configuration of thin film electrical device, the fabrication system may include one or more of the above mentioned apparatus or systems.

Non-limiting examples of apparatus of the fabrication system include a primary level vacuum pump, Kinney Vacuum Booster System KMBD/KT supplied by Brooks Equipment Co.; a substrate or web steering unit, Web Guide Control System supplied by Accuweb; a secondary level vacuum pump, CRYO-TORR 20HP pump system supplied by Helix Technology; a web drive motor, AC Servo Motor and Controller supplied by Motion Industries; a Tension Transducer Roller supplied by Dover Flexo Electronics; a curing oven for organic polymers; a web cleaning unit; and a web treatment system. Alternatives and/or modifications of the above mentioned apparatus will be apparent to those skilled in the art seeking to develop a particular embodiment of a fabrication system for manufacturing or forming a particular embodiment of a thin film electrical device and/or in accordance with certain production constraints/requirements.

The fabrication system can be configured to process continuous lengths of substrate. For example, in one embodiment the fabrication system is configured to process a continuous substrate having a width from about 3 inches to about 108 inches. In another embodiment, the fabrication system is configured to process a continuous substrate having a width from about 8 inches to about 96 inches. And in another embodiment, the fabrication system is configured to process a continuous substrate having a width from about 24 inches to about 84 inches.

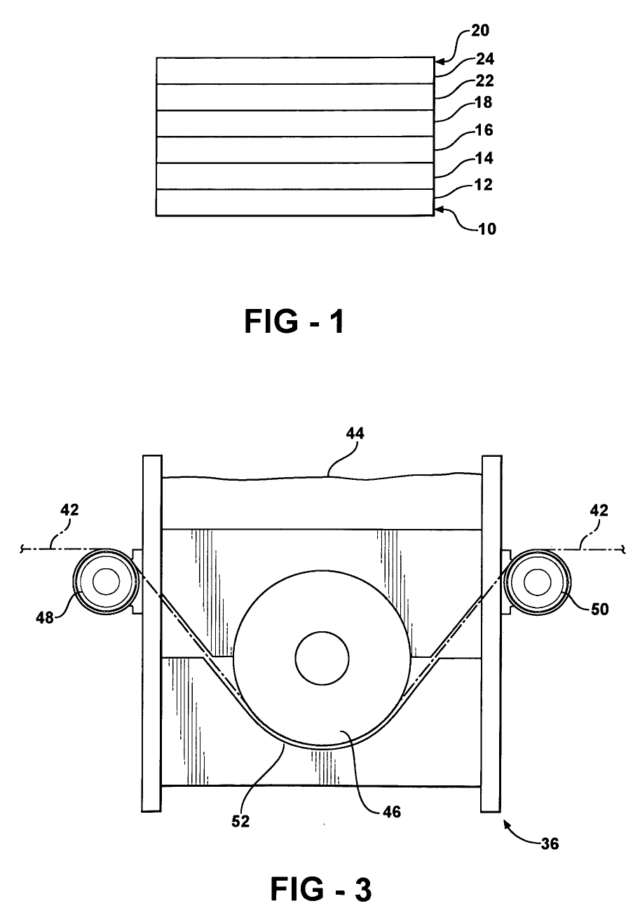

Referring to FIG. 1, an embodiment of an example of a thin film organic electrical device 10, (TFOED), is illustrated, a non-limiting example being an organic photovoltaic device. Device 10 includes a substrate 12, anode 14, p-type semiconductor 16, n-type semiconductor 18, and a cathode 20.

The substrate 12 is transparent material made from glass or a polymer. A transparent polymeric substrate can be any of several types of transparent polymeric materials having a desired strength and flexibility such that the various layers of the TFOED device can be continuously deposited over the substrate. In one exemplary embodiment, the substrate comprises a polyethylene terephthalate (PET) polyester film such as that sold under the MYLAR trademark by E. I. du Pont de Nemours and Company of Wilmington, Del. In other exemplary embodiments, the substrate can comprise other clear, flexible materials such as polyethylene naphthalate (PEN) films, polycarbonate films, clear polyimide, etc.

The anode 14 is a material such as indium tin oxide (ITO) formed in a predetermined pattern over the substrate. The anode material conducts electricity and allows light to be absorbed in the device to generate voltage between the anode and a cathode.

The p-type semiconductor 16 is an electron hole-conductor, also called a hole transport layer (HTL), which includes an organic material formed over the anode. Examples of organic materials that can be used include poly-(2,4)-ethylene-dihydroxy thiophene (PEDOT) or polyaniline (PANI) and the like. In an exemplary embodiment the p-type semiconductor comprises PEDOT (Poly(3,4-ethylenedioxythiophene)). In alternative exemplary embodiments, the system can manufacture thin film electrical devices utilizing other transparent electron hole-conducting materials in addition to or instead of the PEDOT material. These materials include poly (3,4-propylenedioxythiophene) (also referred to herein as “PProDOT”), polystyrenesulfonate (also referred to herein as “PSS”), polyvinylcarbazole (also referred to herein as “PVK”), non-acidic p-type polymers, and other hole-conducting materials and combinations. In an exemplary embodiment, the p-type organic semiconductor 16 is applied over the anode utilizing apparatus or equipment such as coating processes such as ink-jet printing, a roll-coating process, gravure printing, or the like. Generally, to achieve a substantially uniform organic polymer thickness it is desirable that the deposition of the organic polymer layer occur at substantially uniform substrate velocity.

The n-type semiconductor 18 is an organic polymer layer with a conjugated p-electron system along its backbone, allowing the polymer to support positive and negative charge carriers with high mobilities along the chain. Further, the semiconductor 18 layer can contain dopants to modify band gaps of the layer.

In this embodiment, the cathode 20 includes a surface activation layer 22 with a low work function such as a layer of calcium, and a layer of aluminum 24, wherein both layers are vapor-deposited over the n-type semiconductor 18. In alternative exemplary embodiments, the cathode layer be made from several different conductive materials including conductive metals, conductive polymers and like materials.

In another embodiment of a TFED, an intermediate structure is disposed over a substrate and an electric device portion is disposed over the intermediate structure, wherein the intermediate structure includes a plurality of layers to prevent water vapor and oxygen from diffusing through the substrate and degrading the electric device portion. For instance in one non-limiting example of a thin film electrical device, the intermediate structure is a multilayer structure disposed over a plastic substrate (12) and the cross sectional makeup shown in FIG. 1 may instead include an inorganic oxide (14), an organic smoothing layer (16), an inorganic oxide layer (18), an organic smoothing layer (22), and a thin film electrical device (24) disposed over the multilayer intermediate structure. The oxide layers can be vacuum deposited by physical vapor deposition (PVD), plasma enhanced chemical vapor deposition (PECVD), etc. The organic smoothing layer can be deposited at atmospheric pressure. Each of the deposited layers can be cured before deposition of the next material layer thereover. Additionally, the fabrication system can be further configured to form at least a part of the electrical portion over the intermediate structure.

And in another exemplary embodiment, fabrication of a TFED can include a flexible metal foil substrate and application of an organic insulating layer over the substrate before a successive vacuum processing of another layer. For example, a layer of polyimide is deposited and cured at atmospheric pressure before the substrate proceeds to a vacuum environment for deposition of metal layers or other components of the TFED. In another embodiment, fabrication of polymer TFEDs may require deposition and curing of organic semiconductor polymer layers at atmospheric pressure followed by a vacuum deposition of metal contact layers.

In an exemplary embodiment, an encapsulant layer is disposed over the cathode layer or another layer, thereby sealing the thin film layers between the substrate and the encapsulant layer.

The thin film device fabrication system can include one or more drive apparatus configured to advance the substrate through the fabrication system and to control a tension level of the substrate as the substrate advances through the system. The drive apparatus can include components such as a drive roller operably coupled to a motor, a controller, transducers, and guide rollers. In one operation example, the transducers are used to detect a tension level of the substrate. The controller, after receiving data indicative of the tension of the substrate, then sends signals to the motor to adjust the movement of the substrate, for example the speed of the substrate. The transducer can then send a signal indicative of the substrate tension level to a controller and the controller can send a signal to an appropriate motor to accelerate or decelerate the motor's speed. By adjusting the speed of an appropriate motor, the controller can adjust the speed of the drive roller thereby adjusting the tension level of the substrate at the transducer roller.

A variety of sensors can be utilized in the fabrication system to aid in monitoring and controlling of the substrate as it proceeds through the operational processes. For example, an ultrasonic sensor configured to detect the presence of the substrate's edge by detecting reflected acoustical signals can be utilized. Other sensing devices contemplated include optical sensors, sensors utilizing lasers, and like devices can be used to detect the position of the substrate's edge or edges. Likewise, it is contemplated a wide variety of sensors can be used for monitoring and controlling other operation parameters associated with the fabrication system.

The thin film device fabrication system can include a substrate conditioning system to clean a substrate surface, and/or to treat the surface, for example, to increase an adhesion level between the surface of the substrate and a material to be disposed over the surface. The substrate cleaner can be a wet washer unit that uses a low vapor pressure cleaning fluid such as a water-IPA mixture, combined with a hot-air knife drying unit. The water-IPA mixture can contain between 10 and 25% IPA by volume, preferably about 20%. Other substrate cleaning units could be used including a combined static deionizer-vacuum unit, or an elastomer roller/adhesive roller combination. The surface treatment applied to enhance the adhesion of a coating layer to the surface can be a UV/ozone treatment, or vapor treatment with an adhesion promoter such as hexamethyldisilazane (HMDS) or a blend of HMDS and N,N-diethylaminotrimethylsilane (DEATS), or a corona discharge treatment.

The thin film device fabrication system can include an alignment system configured to align the substrate to a predetermined position for entrance into an ATV system, a gas gate, or alignment with deposition apparatus, such as a shadow mask portion of the deposition apparatus. Thus, the alignment system can correct misalignment that can occur prior a process or realign the substrate after it goes through a process of the fabrication system. In another embodiment, the alignment system and the drive apparatus can both be configured to function in a coordinated relationship to maintain the substrate in a desired position, orientation and speed as the substrate progresses through various processes of the fabrication system.

It is contemplated that certain embodiments of thin film electrical devices will dictate an embodiment of a fabrication system that includes a plurality of deposition apparatus/processes for depositing materials over the substrate. The fabrication system is configured so that the continuous substrate engages one or more deposition processes and then passes toward another operational process of the fabrication system.

In one example, deposition apparatus is configured to deposit p-type semiconductor material over the substrate. Deposition apparatus having another configuration can be configured to deposit the n-type semiconductor layer over the substrate. Deposition apparatus can be configured to deposit material over the substrate at a substantially uniform thickness and at a precisely defined pattern without introducing contaminants into the p-type or the n-type semiconductor material. The organic semiconductor material, having desirable properties, can be deposited at atmospheric pressure utilizing deposition apparatus such as one or more of the following devices: a roll coating device such as a patterned or an unpatterned gravure printing device, a flexographic printing device, an ink-jet printing device, a screen printing device, a slot die or a combination thereof. The semiconductor material, inorganic or organic, having desirable properties can also be deposited in a vacuum environment such as by one of the processes discussed hereinabove.

In another exemplary embodiment, deposition apparatus includes successive stations each configured to deposit a material layer such as a barrier layer or a smoothing layer, wherein the plurality of deposited layers form an intermediate structure over which an electrical device portion may be disposed.

It is further contemplated that an embodiment of the fabrication system will utilize curing apparatus configured for conditioning deposited material to a desired compositional state. The curing apparatus can be configured to apply heat, pressure, elements/compounds, gases, energy, etc. to the substrate as it proceeds through the curing apparatus to obtain the desired compositional state. The desired state can be for the finished device or to prepare a particular layer for a subsequent process.

For example, a curing oven can heat deposited material to predetermined temperature depending on desired post-cure material properties and on the durability of the substrate at the heated temperature. Further alternative exemplary embodiments can include other curing devices. For example, the system can utilize heat curing devices that use forms of radiation for curing, for example, microwave radiation, ultraviolet radiation, infrared radiation and the like. In one instance, the amount of time the substrate remains in the curing oven and the temperature therein is selected based on the volatility of a material being dried. In one embodiment, the curing oven operates at a temperature between 50% and 130% of the boiling point of a solvent and the substrate exposure is between 15 minutes and 45 minutes. In another embodiment, the oven chamber temperature, for example 50-200° C., is selected for a water soluble p-type semiconductor. In other exemplary embodiments, the temperature and the retention time can be adjusted as desired to cure the thin film layers. In another embodiment, the curing ovens are configured to control the atmosphere as well as the temperature of the cure.

In another embodiment, the fabrication system includes an embodiment of a vacuum deposition apparatus. For example, a vacuum evaporation deposition apparatus is utilized to deposit materials over the substrate. Deposition apparatus can also be configured to deposit the materials by PVD, PECVD, sputtering, etc. In this particular non-limiting embodiment, the deposition apparatus deposits electrode material utilizing a “deposit up” vacuum thermal evaporation process. The deposition apparatus is configured to evaporate and deposit electrode material over the substrate in a patterned orientation. The substrate is positioned such that bottom side of the substrate receives the deposited electrode material thereon. In the embodiment shown in FIG. 1, the deposited electrode material forms the cathode over the n-type layer. The cathode material is in effective electrical contact with the semiconductor layers. As used herein, the terms “effective electrical contact” refers to sufficient electrical contact such that the cathode can route sufficient current to the semiconductor layers so that the semiconductor layers can operate in their conducting function.

In one embodiment, the deposition apparatus includes a chamber, pumping apparatus, a shadow mask, a camera, and a controller. The chamber is configured so the continuous substrate enters the chamber for the deposition process therein and passes from the chamber toward another operational process of the fabrication system. The pumping apparatus is configured for reducing the pressure inside the chamber. For example, pumping apparatus operably coupled to a chamber of the deposition apparatus, or to any chamber of the fabrication system, can be configured to control the operating pressure within the chamber greater or equal to atmospheric pressure, or to a predetermined vacuum pressure, such as within a medium or high vacuum range. The pumping apparatus may be a vacuum pump such as a diffusion pump or any other device capable of lowering the pressure within the chamber. The pumping apparatus is configured to maintain a pressure within the chamber during an operation where cathode material is deposited over the substrate. For example, the deposition apparatus is configured so chamber pressure can be maintained at a pressure in a range from 10⁻² torr to 10⁻⁸ torr during operation to deposit electrode or cathode material via one of the deposition processes described hereinabove.

In one embodiment, a shadow mask of deposition apparatus has open areas disposed therethrough. During a deposition operation, the shadow mask and the substrate are orientated with respect to each other such that cathode material is deposited over selected areas of the substrate through the open areas of the shadow mask so that the deposited cathode material forms a predetermined pattern on the substrate. In one embodiment, the shadow mask is a retained in a stationary position and a portion of the substrate is moved to a stationary position relative to the open areas of the shadow mask during a deposition operation. In another embodiment, the shadow mask can be configured to move synchronously with a moving portion of the substrate such that the open areas of the shadow mask align with the moving portion of the substrate that receives the deposited cathode material through the open areas.

The camera and the controller are configured such that the camera is directed to capture an image edge of the pattern on the substrate. The controller then compares the captured image to a desired image and determines a movement direction and distance of the substrate so material can be deposited over the substrate in a desired position and pattern. Thus, the cathode material forms a patterned shape on the substrate substantially the same as the patterned opening areas of the shadow mask.

In another embodiment, the fabrication system can include a vacuum deposition apparatus that includes a plurality of deposition chambers each configured to receive therethrough the continuous substrate and wherein a different material layer is deposited over the substrate in each chamber. The deposition apparatus can further include a substrate movement and positioning system/apparatus configured to guide the continuous substrate through the various chambers at a desired time and position. Components of the substrate movement and positioning system can be positioned before, after and in between the chambers. The substrate movement and positioning system can include a controller configured to provide instructions to the components of the system to move/position the substrate and/or shadow mask. Additionally, the vacuum deposition apparatus can further include sealing mechanisms configured to aid in maintaining a desired pressure in each of the chambers.

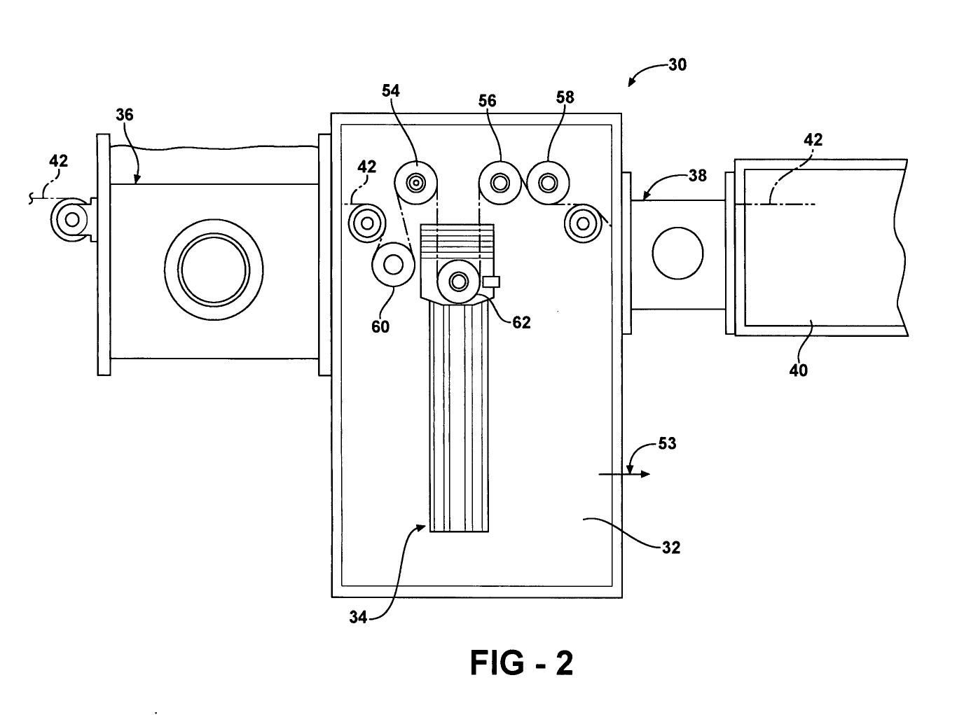

Referring to FIG. 2, for example and in one embodiment, an air-to-vacuum (ATV) system 30 includes a chamber 32 having substrate accumulator apparatus 34 (a substrate movement and positioning system) therein, gas gates 36, 38, and a vacuum deposition chamber 40 is illustrated, for example for manufacturing the device of FIG. 1. The vacuum deposition chamber 40 can be configured to deposit materials, in one or more chambers, over the incoming substrate 42 as shown in FIG. 2. In one embodiment, during a deposition operation, chamber 32 is configured to operate at approximately 1.0 torr and chamber 40 is configured to operate at approximately from 10⁻² torr to 10⁻⁸ torr. The gas gates 36, 38 are sealing mechanisms configured to aid in transitioning operating pressures at various positions along the ATV system. The gas gates are configured so the continuous substrate can move from a first gaseous environment to a second gaseous environment while separate pressures are maintained in the two environments. Each of the gas gates 36, 38 have components that function substantially in a similar manner even though the size of the components may not be the same and therefore only gas gate 36 will be discussed hereinbelow.

Referring to FIG. 3, gas gate 36 includes a housing 44, a cylinder 46, a first guide roller 48, and a second guide roller 50. The cylinder and guide rollers are configured and positioned with respect to one another so the continuous substrate can move over a surface of the guide rollers and the cylinder and so the substrate maintains contact with the cylinder without coming in contact with the housing 44. Additionally, each of the guide rollers 48, 50 have a recessed portion along the length of the rollers so a previously deposited material (e.g. an electrically active material) over the continuous substrate does not contact a peripheral portion of the rollers as the substrate passes over the rollers. Depending on the configuration of the device including the active areas, the rollers can have multiple recessed portions.

The substrate moves through a gap 52 formed between the housing and the cylinder. The gap is sufficiently sized so the substrate maintains contact with the cylinder without coming in contact with the housing. The gap and the substrate wrap amount against the cylinder are configured to maintain the desired pressures in the regions in cooperation with pumping apparatus in fluid communication with the respective chambers. The gap is sized so during a deposition operation as gas flows through the gap between adjoining gaseous regions, the gas velocity reaches the speed of sound in the gap. When the gas velocity reaches the speed of sound, the gas conductance through the gap becomes “choked” and any decrease in the adjoining pressure regions results in no further increase in gas flow in the gap. The function of the gas gates 36, 38 of the present disclosure is similar to the gas gate described in U.S. Pat. No. 6,878,207, the contents of which are herein incorporated by reference.

Referring to FIG. 2, the gas gate 36 is positioned between an atmospheric region and a region within chamber 32 at approximately 1.0 torr. The gas gate 38 is positioned between chamber 32 and chamber 40 at approximately 10⁻⁵ torr. Pumping apparatus 53 is in fluid communication with the interior of chamber 32 and cooperates with the gas gates 36, 38 to maintain a desirable operating pressure within the chamber 32. Likewise, chamber 40 also includes pumping apparatus (not shown) operably joined to the chamber and cooperates with the gas gate 38 to maintain an operating pressure within the chamber 40. In another embodiment, deposition chamber 40 can include a plurality of chambers and more than one pumping apparatus cooperating with the chambers.

During a vacuum deposition of the cathode material, a relatively low pressure, such as 10⁻⁵ torr, is desirable. Additionally, it is desirable to move the coated substrate from the atmospheric region to the high vacuum region without contacting the active area of the coated substrate during the transfer. Hence, the deposition apparatus, and in particular the gas gates and the operation of the pumping apparatus, are configured to pass the substrate therethrough and transition to the high vacuum pressure in a desirable, practical, cost-efficient manner.

There is a relationship between the gas gate gap configuration and the size of pumping apparatus for pumping gaseous materials from a chamber in fluid communication with the gas gate gap. For example, for a given width of a substrate, a gas gate with a large cross sectional gap dimension leads to use of large volume capacity pumping apparatus. For the same width of substrate, a gas gate with a relatively very narrow cross sectional gap dimension then can be used with lower volume capacity pumping apparatus. Cost is also a factor as it costs more to manufacture gas gates with a very narrow gap and it costs more to manufacture very large volume capacity pumping apparatus. In another approach, the use of multiple gas gates with more open gap dimensions can be used to transition from one pressure region to another and allow the use of pumping apparatus with lower volume capacity.

Additionally, the configuration shown in FIG. 2 provides the capability of routing a portion of the continuous substrate to the vacuum deposition chamber(s) in a manner so the substrate can be stopped for patterned deposition at a stationary shadow mask within the chamber while other areas of the continuous substrate move along other portions of the fabrication system. The accumulator apparatus 34 within chamber 32 is configured to control the motion of the substrate into the chamber(s) 40 of the vacuum deposition apparatus.

Vacuum deposition of patterned thin film layers typically requires stopping the substrate for static deposition using a shadow mask or other patterning technique. One technique for stopping a moving substrate is to use an accumulator device with one or more moving rollers to gather or collect a portion of the substrate within an interior portion of the chamber having the accumulator apparatus while stopping another section of substrate outside the chamber for a static process. It is also generally not desirable to operate the accumulator apparatus in a pressure environment of say approximately 10⁻³ torr or less because of the difficulties with moving parts in a vacuum, outgassing, particulate generation, etc.

In an exemplary embodiment, another accumulator apparatus substantially similar to apparatus 34, within a respective chamber, is positioned on the other side of the vacuum deposition chamber 40. The two accumulator apparatus are configured/synchronized to function together to stop a portion of the substrate within the chamber 40 while the substrate before accumulator apparatus 34 and after the accumulator apparatus on the other side of chamber 40 continue to move at a substantially constant predetermined speed. The two accumulators are configured to function together to provide a step-and-repeat movement of the substrate within the chamber 40 so deposition of the cathode material can occur at a optimum rate in a patterned manner to provide for desirable cathode configuration/material properties.

In an exemplary embodiment as illustrated in FIG. 2, the accumulator apparatus 34 includes guide rollers 54, 56, 58; drive roller 60 (optional); and translational roller 62. Guide rollers 54 and 56 each include a recessed portion along their length so the active area of the substrate does not contact the roller as the substrate passes over the rollers, similar to the recessed areas of the guide rollers 48, 50 of the gas gates 36, 38 discussed hereinabove. The accumulator apparatus 34 is configured so the translational roller 62 moves along a vertical direction toward and away from the guide rollers 54, 56, 58 as shown. As the translational roller moves away from the guide rollers, it urges a length of substrate away from the guide rollers, and collects an additional amount of substrate within chamber 32. During this transition, a portion of the substrate within the chamber 40 is effectively stopped.

At the other accumulator apparatus on the other side of the chamber 40, the corresponding translational roller is positioned closer to the guide rollers of that accumulator apparatus when the translational roller 62 is positioned farther away from the guide rollers of accumulator apparatus 34 in chamber 32. When it is desirable to move the portion of the substrate within the vacuum chamber, the two translational rollers (of the respective accumulator apparatus) just described switch vertical positions, thereby taking up and moving down substrate within the respective chambers having the accumulator apparatus.

Additionally and an in another embodiment, the substrate movement and positioning system can further include one or more guide rollers between each of a plurality of vacuum deposition chambers of the ATV system. The guide rollers can be spaced apart, aligned and offset with respect to each other to provide tension to the substrate between the deposition chambers and further to aid in controlling the movement, speed and position of the substrate.

While the foregoing description has been directed to certain embodiments of fabrication systems for manufacturing thin film electrical devices, the principles of this invention are contemplated of being extended to incorporate apparatus/processes not disclosed herein to other embodiments of the fabrication system. In view of the teachings presented herein, yet other modifications and variations of the invention will be apparent to those of skill in the art. The foregoing is illustrative of particular embodiments, but is not meant to be a limitation upon the practice thereof. It is the following claims, including all equivalents, which define the scope of the invention.

What is claimed is:

1. A system for manufacturing a thin film electrical device on a substrate, the system comprising:
deposition apparatus configured for depositing material over a portion of the substrate within a chamber of the deposition apparatus;
first gas evacuation apparatus in fluid communication with the chamber of the deposition apparatus;
a first chamber having accumulating apparatus therein configured for gathering a portion of the substrate within the first chamber;
second gas evacuation apparatus in fluid communication with the first chamber;
a first gas gate providing fluid communication between the first chamber and the chamber of the deposition apparatus; and
wherein the substrate with an accumulated portion of substrate in the first chamber extends through the first chamber and into the chamber of the deposition apparatus and through the first gas gate; and the first gas gate, the gas evacuation apparatus of the chamber of the deposition apparatus and the gas evacuation apparatus of the first chamber are configured so an operational pressure in the chamber of the deposition apparatus is lower than an operational pressure in the first chamber.

2. The system of claim 1, wherein the accumulating apparatus is further configured for varying a quantity of substrate gathered in the first chamber.

3. The system of claim 1, further comprising a second gas gate providing fluid communication between the first chamber and a region outside the first chamber, and the substrate further extends through the second gas gate.

4. The system of claim 3, wherein the region outside the first chamber is at atmospheric pressure, the operational pressure within the first chamber is in a range of 10 torr and 0.01 torr, and the operational pressure within the chamber of the deposition apparatus is in a range of 10⁻² torr to 10⁻⁶ torr.

5. The system of claim 1, wherein the material deposited over the substrate is electrically conducting material.

6. The system of claim 1, wherein the operational pressure within the chamber of the deposition apparatus is in a range of a medium vacuum.

7. The system of claim 6, wherein the operational pressure within the chamber of the deposition apparatus is in a range of 10⁻⁶ torr to 10⁻⁸ torr.

8. The system of claim 1, wherein the operational pressure within the chamber of the deposition apparatus is in a range of 10⁻² torr to 10⁻⁶ torr.

9. The system of claim 1, wherein the operational pressure within the chamber of the deposition apparatus is at approximately 10⁻⁵ torr.

10. The system of claim 1, wherein the operational pressure within the chamber of the deposition apparatus is in a range of 10⁻² torr to 10⁻⁶ torr and the operational pressure within the first chamber is in a range of 10 torr and 0.01 torr.

11. The system of claim 10, wherein the operational pressure within the chamber of the deposition apparatus is at approximately 10⁻⁵ torr and the operational pressure within the first chamber is at approximately 1.0 torr.

12. The system of claim 1, wherein the deposition apparatus is configured for depositing material over the substrate by vacuum evaporation deposition.

13. The system of claim 1, wherein the deposition apparatus is configured for depositing material over the substrate by sputtering.

14. The system of claims 12 or 13, wherein the material deposited over the substrate is electrically conducting material.

15. The system of claim 14, wherein an electrode is formed.

16. The system of claim 1, wherein the deposition apparatus is configured for depositing the material over the substrate in a predetermined pattern.

17. The system of claim 16, wherein the deposition apparatus includes a shadow mask.

18. The system of claim 17, wherein the deposition apparatus is configured so the substrate and the shadow mask move to deposit the material over the substrate.

19. The system of claim 1, further comprising deposition apparatus for depositing organic material over the substrate.

20. The system of claim 18, wherein the organic material is a semiconducting polymer.

21. The system of claim 1, further comprising a second gas gate providing fluid communication between the first chamber and a region outside the first chamber, and the substrate further extends through the second gas gate.

22. The system of claim 21, wherein the region outside the first chamber is at atmospheric pressure, the operational pressure within the first chamber is in a range of 10 torr and 0.01 torr, and the operational pressure within the chamber of the deposition apparatus is in a range of 10⁻² torr to 10⁻⁶ torr.

23. The system of claim 1, further comprising deposition apparatus for depositing a barrier layer over the substrate.

24. The system of claim 1, further comprising deposition apparatus for depositing a smoothing layer over the substrate.

25. The system of claim 1, further comprising a drive system for moving the substrate.

26. The system of claim 1, further comprising a steering system for aligning the substrate.

27. The system of claim 1, further comprising a lamination system for encapsulating the thin film electrical device after the material is deposited over the substrate.

28. A system for manufacturing a thin film electrical device on a substrate, the system comprising:
deposition apparatus configured for depositing material over a portion of the substrate within a chamber of the deposition apparatus;
first gas evacuation apparatus in fluid communication with the chamber of the deposition apparatus;
a first chamber and a second chamber, the deposition apparatus positioned between the first chamber and the second chamber, each of the first and second chambers having accumulating apparatus therein configured for gathering a portion of the substrate within the corresponding first and second chamber;
second gas evacuation apparatus in fluid communication with the first chamber;
third gas evacuation apparatus in fluid communication with the second chamber;
a first gas gate providing fluid communication between the first chamber and the deposition apparatus;
a second gas gate providing fluid communication between the chamber of the deposition apparatus and the second chamber; and
wherein the substrate with an accumulated portion of substrate in the first chamber and an accumulated portion of substrate in the second chamber extends through the first chamber, through the chamber of the deposition apparatus and through the second chamber and though the first and second gas gates; and the first and second gas gates, the first, second and third gas evacuation apparatus are configured so an operational pressure in the chamber of the deposition apparatus is lower than an operational pressure in each of the first and second chambers.

29. The system of claim 28, wherein the accumulating apparatus in the first chamber or the second chamber is further configured for varying a quantity of substrate gathered in the respective chamber.

30. The system of claim 28, further comprising a third gas gate and a fourth gas gate, the third gas gate providing fluid communication between the first chamber and a region outside the first chamber, the fourth gas gate providing fluid communication between the second chamber and a region outside the second chamber, and the substrate further extends through the third and fourth gas gates.

31. The system of claim 30, wherein the region outside the first chamber and the region outside the second chamber are each at atmospheric pressure, the operational pressure within the first chamber and the second chamber is in a range of 10 torr and 0.01 torr, and the operational pressure within the chamber of the deposition apparatus is in a range of 10⁻² torr to 10⁻⁶ torr.

32. The system of claim 31, wherein the deposition apparatus is configured for depositing material by vacuum evaporation deposition.

33. The system of claim 31, wherein the deposition apparatus is configured for depositing the material over the substrate in a predetermined pattern.

34. The system of claim 28, further comprising deposition apparatus for depositing organic material over the substrate.

35. The system of claim 34, wherein the organic material is a semiconducting polymer.

36. The system of claim 28, further comprising a drive system for moving the substrate, a steering system for aligning the substrate, and curing apparatus.

37. The system of claim 28, further comprising lamination apparatus for encapsulating the thin film device after the material is deposited over the substrate.

38. A system for manufacturing a thin film electrical device on a substrate, the system comprising:
a chamber having accumulating apparatus therein configured for gathering a portion of the substrate within the chamber; and
a gas gate providing fluid communication between a pressure region of the chamber and a second pressure region.

39. The system of claim 38, wherein the second region is at atmospheric pressure and the operational pressure within the chamber is in a range of approximately 10 torr and approximately 0.01 torr.

40. The system of claim 38, further comprising deposition apparatus and a second gas gate positioned between the chamber and the chamber of the deposition apparatus, the deposition apparatus configured for depositing material over a portion of the substrate within a chamber of the deposition apparatus.

41. The system of claim 40, wherein an operational pressure within the chamber of the deposition apparatus is in a range of 10⁻² torr to 10⁻⁸ torr.

42. The system of claim 41, wherein the operational pressure within the chamber of the deposition apparatus is at approximately 10⁻⁵ torr and the operational pressure within the chamber having the accumulator apparatus is at approximately 1.0 torr.

43. The system of claim 40, wherein the deposition apparatus comprises a shadow mask configured for depositing material over the substrate in a predetermined pattern.

44. The system of claim 40, further comprising a second deposition apparatus configured for depositing an organic material over the substrate.

45. The system of claim 44, wherein the organic material is a semiconducting polymer.

46. The system of claim 38, further comprising deposition apparatus configured for depositing a barrier layer in a vacuum over the substrate.

47. The system of claim 38, further comprising deposition apparatus configured for depositing a smoothing layer at atmospheric pressure over the substrate.

48. The system of claim 38, wherein the substrate is a continuous substrate and a supply of the continuous substrate is provided to the system and after the supply of continuous substrate is processed by the system, the processed continuous substrate is collected.

49. A method of utilizing a system for manufacturing a thin film electrical device on a substrate, the system comprising deposition apparatus positioned between a first chamber and a second chamber, a first gas gate providing fluid communication between the first chamber and the chamber of the deposition apparatus, a second gas gate providing fluid communication between the chamber of the deposition apparatus and the second chamber, each of the first chamber, the second chamber and the chamber of the deposition apparatus having gas evacuation apparatus connected thereto in fluid communication with the corresponding chamber, the method comprising:
extending the substrate through the first chamber, the chamber of the deposition apparatus and the second chamber and through the first and second gas gates, wherein each of the first and second chambers includes therein an accumulated portion of the substrate; and
operating the deposition apparatus to deposit material over a portion of the substrate, wherein an operational pressure within the chamber of the deposition apparatus is lower than an operational pressure in each of the first and second chambers.

50. The method of claim 49, wherein the material deposited forms an electrode.

51. The method of claim 49, further depositing an organic material over the substrate, and the system further comprises organic material deposition apparatus.

52. The method of claim 51, wherein the organic material deposited is a semiconducting polymer.

53. The method of claim 49, controlling each of the accumulating apparatus within the first and second chambers so while the substrate is stationary in the deposition chamber one of the accumulating apparatus gathers more substrate within its respective first chamber and the other accumulating apparatus reduces an amount of substrate within it respective second chamber.
